(19) United States
(12) Patent Application Publication
(10) Pub. No.: US 2008/0220579 A1
(43) Pub. Date: Sep. 11, 2008

(54) STRESS ENHANCED MOS TRANSISTOR AND METHODS FOR ITS FABRICATION

(75) Inventors: Rohit PAL, Fishkill, NY (US); David BROWN, Pleasant Valley, NY (US); Scott LUNING, Poughkeepsie, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/683,174

(22) Filed: Mar. 7, 2007

(51) Int. Cl. H01L 21/336; H01L 29/94

(52) U.S. Cl. 438/265; 257/288; 257/E29.345; 257/E21.409

(57) ABSTRACT

According to a method for fabricating a stress enhanced MOS device having a channel region at a surface of a semiconductor substrate, first and second trenches are etched into the semiconductor substrate, the first trench having a first side surface, and the second trench having a second side surface. The first and second side surfaces are formed astride the channel region. The first and second side surfaces are then oxidized in a controlled oxidizing environment to thereby grow an oxide region. The oxide region is then removed, thereby repositioning the first and second side surfaces closer to the channel region. With the first and second side surfaces repositioned, the first and second trenches are filled with SiGe.

### TECHNICAL FIELD

The present invention generally relates to MOS transistors and to methods for their fabrication, and more particularly relates to stress enhanced MOS transistors and to methods for fabricating such transistors with embedded material adjacent the transistor channel.

### BACKGROUND

The majority of present day integrated circuits (ICs) incorporate a plurality of interconnected field effect transistors (FETs), also called metal oxide semiconductor field effect transistors (MOSFETs), or simply MOS transistors. A MOS transistor includes a gate electrode as a control electrode, which is disposed between spaced apart source and drain electrodes between which a current can flow. A control voltage applied to the gate electrode controls current flow through a channel between the source and drain electrodes.

The complexity of ICs and the number of devices incorporated in ICs are continually increasing. There is a continuing demand for the number of devices in an IC to be increased, although this demand conflicts with the concurrent demand for a decrease in the overall IC size. As a solution, research is continually directed to reducing the size of individual MOS transistors and other devices incorporated into an IC. Device size in an IC is usually noted by the minimum feature size, which is the minimum line width or the minimum spacing allowed by circuit design rules. As the semiconductor industry moves to a minimum feature size of 45 nanometers (nm) and even smaller, there is a possibility for performance of individual devices to degrade as the result of scaling. As new generations of integrated circuits are designed, along with the transistors that are used to implement those integrated circuits, technologists rely on non-conventional elements to boost device performance.

The performance of a MOS transistor, as measured by its current carrying capability, is proportional to the mobility of the majority carrier in the transistor channel. It is known that applying a longitudinal stress to the channel of an MOS transistor can increase the carrier mobility; a compressive longitudinal stress enhances the mobility of majority carrier holes and a tensile longitudinal stress enhances the mobility of majority carrier electrons. For example, embedding silicon germanium (SiGe) adjacent to the transistor channel will produce a longitudinal compressive stress that enhances the mobility of holes in P-channel MOS (PMOS) transistors. To fabricate such a device, a trench or recess is etched into the silicon substrate in the source and drain areas of the transistor and the trench is refilled by selective epitaxial growth of the SiGe.

Proximity of embedded SiGe to the transistor gate is highly advantageous as it helps achieve performance targets for the transistor and the overall IC in which the transistor is incorporated. However, conventional methods for etching a trench into the silicon substrate are insufficiently controllable, making it difficult to consistently and precisely bring the trench that is to be filled with SiGe to a suitable proximity to the transistor gate.

Accordingly, it is desirable to optimize methods for fabricating stress enhanced MOS transistors. In addition, it is desirable to provide an optimized stress enhanced MOS transistor that avoids the problems attendant with conventional transistor fabrication such as insufficient proximity of embedded SiGe to an adjacent transistor gate. Furthermore, other desirable features and characteristics of the present invention will become apparent from the subsequent detailed description and the appended claims, taken in conjunction with the accompanying drawings and the foregoing technical field and background.

### SUMMARY OF THE INVENTION

According to one embodiment of the invention, a method is provided for fabricating a stress enhanced MOS device having a channel region at a surface of a semiconductor substrate having a first lattice parameter. First and second trenches are etched into the semiconductor substrate, the first trench having a first side surface, and the second trench having a second side surface. The first and second side surfaces are formed astride the channel region. Then, the first and second side surfaces are oxidized in a controlled oxidizing environment to thereby grow an oxide region. The oxide region is then removed, thereby repositioning the first and second side surfaces closer to the channel region. With the first and second side surfaces repositioned, the first and second trenches are filled with a material having a second lattice parameter that is different than the first lattice parameter.

According to another embodiment, the method further includes forming a gate electrode overlying the gate insulator. Sidewall spacers are also formed astride the gate electrode. When etching the trenches, the first and second side surfaces are aligned with the sidewall spacers. Then, the first and second side surfaces are oxidized in a controlled oxidizing environment to thereby grow the oxide region. The oxide region is then removed, thereby repositioning the first and second side surfaces closer to the channel region. With the first and second side surfaces repositioned, the first and second trenches are filled with the SiGe.

According to yet another embodiment, a stress enhanced MOS transistor is provided. The transistor includes a semiconductor substrate having a channel region formed therein, a gate insulator overlying the channel region, a gate electrode overlying the gate, sidewall spacers formed astride the gate electrode, and first and second SiGe filled trenches formed astride the channel region and underlying the sidewall spacers.

### BRIEF DESCRIPTION OF THE DRAWINGS

The present invention will hereinafter be described in conjunction with the following drawing figures, wherein like numerals denote like elements, and wherein

FIG. 1-6 illustrate, in cross section, a stressed MOS transistor and method steps for its fabrication in accordance with various embodiments of the invention

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

Monocrystalline silicon, the most common semiconductor material used in the semiconductor industry for the fabrication of semiconductor devices and integrated circuits, is characterized by a lattice constant, which is a dimension of the silicon crystal. By substituting atoms other than silicon in a crystal lattice, the size of the resulting crystal and the lattice constant can be changed. If a larger substitutional atom such as a germanium atom is added to the silicon lattice, the lattice constant increases in proportion with the increasing concentration of the larger substitutional atom. Similarly, if a smaller substitutional atom such as a carbon atom is added to the silicon lattice, the lattice constant decreases in proportion with the increasing concentration of the smaller substitutional atom. Locally adding a material having a different lattice parameter than the substrate lattice parameter creates a stress on the host lattice. In a more particular sense, locally adding a large substitutional atom to a host silicon lattice creates a compressive stress on the host lattice, while adding a small substitutional atom to a host silicon lattice creates a tensile stress on the host lattice. Germanium is a relatively large atom compared to silicon. Consequently, the germanium content of embedded SiGe in a transistor channel distorts the silicon crystal lattice and thereby induces compressive stress to the channel, which in turn increases the mobility of majority carrier holes in the transistor.

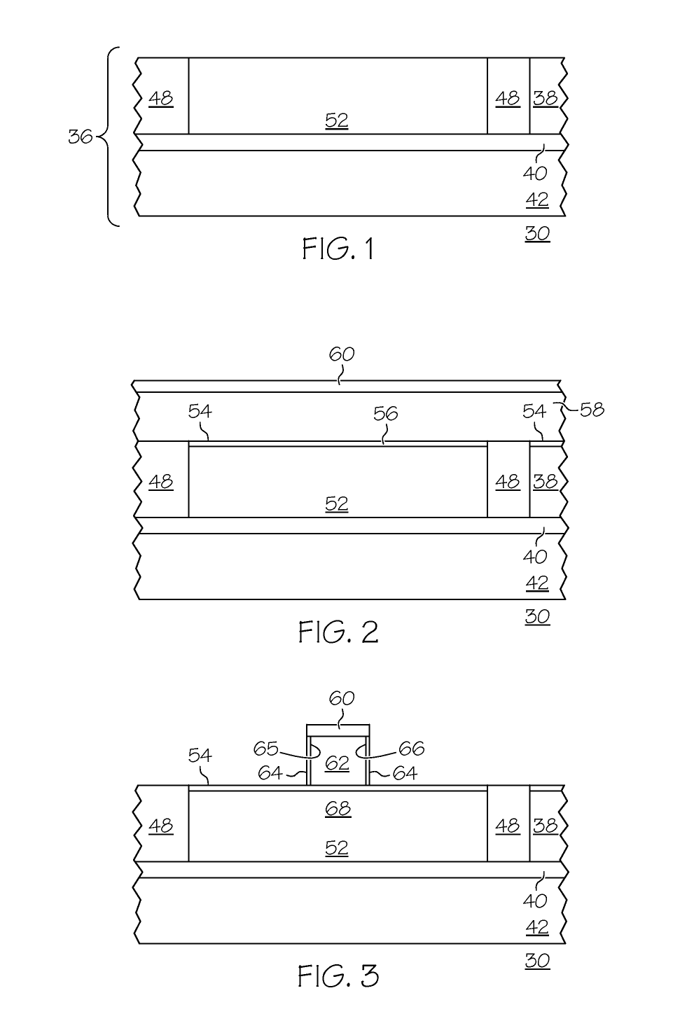

FIGS. 1-6 illustrate, in cross section, a stressed MOS device 30 as constructed during progressive fabrication method steps in accordance with various embodiments of the invention. In this illustrative embodiment the MOS device 30 is depicted as a single P-channel MOS (PMOS) transistor. An integrated circuit formed from stressed MOS devices such as device 30 may include a large number of such transistors, and may also include unstressed PMOS transistors and stressed and unstressed N-channel MOS (NMOS) transistors as well.

Various steps in the manufacture of MOS transistors are well known and so, in the interest of brevity, many conventional steps will only be mentioned briefly herein or will be omitted entirely without providing the well known process details. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

As illustrated in FIG. 1, the manufacture of a stressed MOS transistor 30 in accordance with an embodiment of the invention begins with providing a semiconductor substrate 36 in and on which such transistors are fabricated. The initial steps in the fabrication of MOS transistor 30 are conventional and will not be described in detail. The semiconductor substrate is preferably a silicon substrate having a (100) surface crystal orientation wherein the term “silicon substrate” and “silicon layer” are used herein to encompass the relatively pure monocrystalline silicon materials typically used in the semiconductor industry as well as silicon admixed with other elements such as germanium, carbon, and the like. Semiconductor substrate 36 will hereinafter be referred to for convenience but without limitation as a silicon substrate although those of skill in the semiconductor art will appreciate that other semiconductor materials could be used. Silicon substrate 36 may be a bulk silicon wafer (not illustrated), or preferably is a thin monocrystalline layer of silicon 38 on an insulating layer 40 (commonly know as silicon-on-insulator or SOI) that, in turn, is supported by a carrier wafer 42. Thin silicon layer 38 typically has a thickness of less than about 100 nanometers (nm) depending on the circuit function being implemented. The thin silicon layer preferably has a resistivity of at least about 1-35 Ohms per square. The silicon can be impurity doped either N-type or P-type, but is preferably doped P-type. Dielectric insulating layer 40, typically silicon dioxide, preferably has a thickness of about 50-200 nm.

Isolation regions 48 are formed that extend through monocrystalline silicon layer 38 to dielectric insulating layer 40. The isolation regions are preferably formed by well known shallow trench isolation (STI) techniques in which trenches are etched into monocrystalline silicon layer 38, the trenches are filled with a dielectric material such as deposited silicon dioxide, and the excess silicon dioxide is removed by chemical mechanical planarization (CMP). STI regions 48 provide electrical isolation, as needed, between various devices of the circuit that are to be formed in monocrystalline silicon layer 38. Either before or preferably after fabrication of the STI regions, selected portions of silicon layer 38 can be impurity doped, for example by ion implantation. For example, an N-type well 52 can be impurity doped N-type for the fabrication of PMOS transistor 30.

A layer of gate insulator 56 is formed on a surface of the silicon layer 38 and also on a surface of the well 52 as illustrated in FIG. 2. The gate insulator may be thermally grown silicon dioxide that is formed by heating the silicon substrate in an oxidizing ambient, or may be a deposited insulator such as a silicon oxide, silicon nitride, a high dielectric constant insulator such as HfSiO, or the like. Deposited insulators can be deposited in a known manner such as, for example, by chemical vapor deposition (CVD), low pressure chemical vapor deposition (LPCVD), semi-atmospheric chemical vapor deposition (SACVD), or plasma enhanced chemical vapor deposition (PECVD). Gate insulator 56 is here illustrated as a thermally grown silicon dioxide layer that grows only on a surface of silicon layer 38. The gate insulator material is typically 1-10 nm in thickness and preferably a thickness of about 1-2 nm. In accordance with one embodiment of the invention a layer of gate electrode forming material 58, preferably polycrystalline silicon, is deposited onto a surface 54 of the gate insulator 56. Other electrically conductive gate electrode forming materials such as metals and metal silicides may also be deposited by providing the material by itself or with appropriate impurity doping to set the necessary threshold voltage of the transistor. The gate electrode forming material 58 will hereinafter be referred to as polycrystalline silicon although those of skill in the art will recognize that other materials can also be employed. If the gate electrode material 58 is polycrystalline silicon, that material is typically deposited to a thickness of about 50-200 nm and preferably to a thickness of about 100 nm by LPCVD by the hydrogen reduction of silane. The layer of polycrystalline silicon is preferably deposited as undoped polycrystalline silicon and is subsequently impurity doped by ion implantation. A layer of hard mask material 60 such as a layer of silicon nitride is deposited over the polycrystalline silicon gate electrode forming material. The layer of masking material, if silicon nitride, can be deposited, for example, by PECVD to a thickness of about 40 to 50 nm from the reaction of dichlorosilane and ammonia. Those of skill in the art will understand that other dielectric materials other than silicon nitride can be deposited as the hard mask material.

As depicted in FIG. 3, gate electrode forming material 58 and hard mask material 60 are photolithographically patterned and etched to form a gate electrode 62 overlaid by the hard mask material 60. The polycrystalline silicon can be etched in the desired pattern by, for example, plasma etching in a Cl or HBr/O₂ chemistry and the hard mask can be etched, for example, by plasma etching in a CHF₃, CF₄, or SF₆ chemistry. Following the patterning of the gate electrode 62, in accordance with one embodiment of the invention, a thin layer 64 of silicon oxide is thermally grown on the opposing sidewalls 65 and 66 of gate electrode 62. When included as part of the transistor, the thin oxide layer 64 has a thickness, for example, of about 2-4 nm. The formation of gate electrode 62 defines a channel region 68 as that portion at the surface of thin silicon layer 38 underlying the gate electrode. Preferably the channel is oriented along a [110] crystal direction so that current flow in the transistor will be in the [110] crystal direction, though those skilled in the art will appreciate that numerous other orientations for the current flow may be implemented. Thin oxide layer 64 provides a liner to separate the polycrystalline silicon gate electrode from subsequently deposited spacer forming materials.

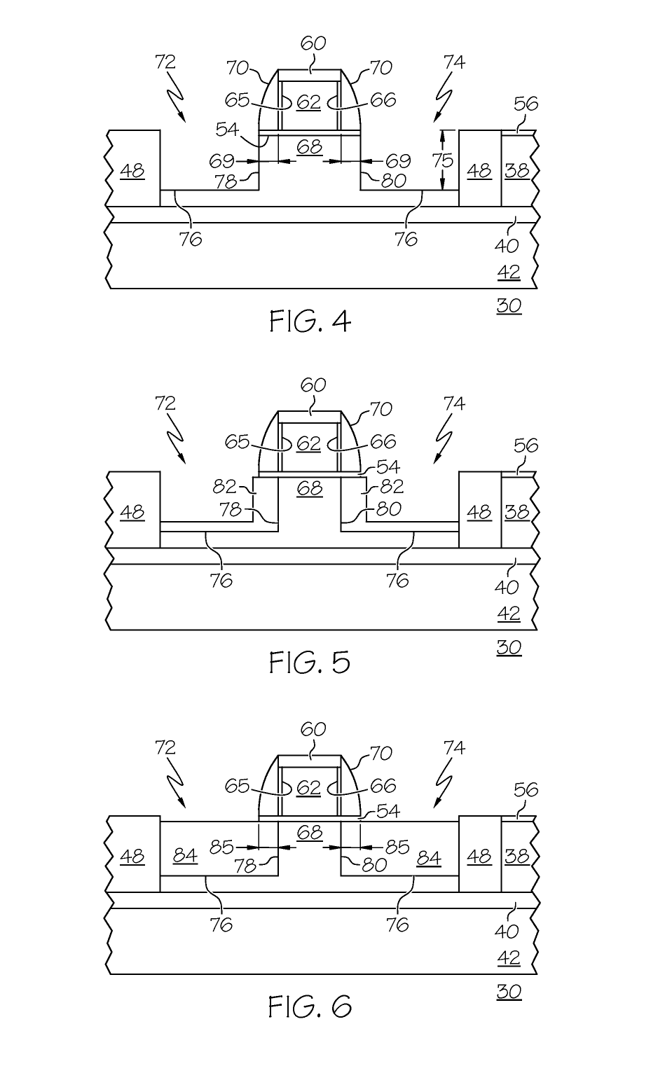

The method in accordance with one embodiment of the invention continues by blanket depositing a layer of silicon nitride or other spacer forming material (not illustrated) and anisotropically etching the layer to form sidewall spacers 70 overlying thin layer 64 of silicon oxide on opposing sidewalls 65 and 66 as illustrated in FIG. 4. According to an exemplary embodiment, the silicon nitride layer is deposited to a thickness ranging between about 7 and about 20 nm by LPCVD using dichlorosilane and ammonia as reactants. The sidewall spacers 70 may be anisotropically etched, for example by reactive ion etching (RIE), using CF₄, CHF₃, C₄F₈, or CH₂F₂ chemistries or a combination thereof. Trenches 72 and 74 are etched into thin silicon layer 38 using spacers 70, gate electrode 62, and STI 48 as etch masks. Because the sidewall spacers are used as an etch mask, the trenches are self aligned to sidewalls 65 and 66 of gate electrode 62 and to channel region 68 and are spaced apart from the gate electrode by a distance substantially equal to the thickness of the sidewall spacers as indicated by arrows 69. Trenches 72 and 74 are anisotropically etched, for example, by reactive ion etching (RIE) using a HBr/O₂ chemistry to a depth of about 50-60 nm as indicated by arrows 75. At least a thin portion of silicon layer 38 is left beneath the trenches' bottom surfaces 76. Trenches 72 and 74 have side surfaces 78 and 80, respectively that are formed astride the channel region 68. Bottom surface 76 is substantially parallel to and has the same crystal orientation as surface 56 of thin silicon layer 38.

Although trenches 72 and 74 will be filled with SiGe in subsequent steps, FIGS. 5 to 6 depict processing steps for enabling increased proximity between the SiGe and the channel region 68 prior to filling the trenches 72 and 74. Such proximity is highly advantageous as it enables the production of a transistor having a relatively small size and increases current output from the PMOS transistor 30. However, since the trenches 72 and 74 are formed by anisotropic etching, the sidewall spacers affect the location of the side surfaces 78 and 80, which in turn define the SiGe boundary and its proximity to the channel region 68. There is a fundamental thinness limit for the sidewall spacers 70, because after filling the trenches 72 and 74 with SiGe, the sidewall spacers 70 should be thick enough to continue to protect the transistor polycrystalline during subsequent etching, epitaxy pre-cleans, and epitaxy pre-bakes. If the spacer thickness in the sidewall spacers 70 is reduced to less than 5 nm during such processing steps, the spacers' abilities to protect the polycrystalline may be compromised. It is therefore preferred that the sidewall spacers 70 have a thickness of at least about 7 nm during formation of the trenches 72 and 74, which in turn defines the SiGe boundary as being no closer than about 7 nm to the channel region 68.

Turning to FIG. 5, an oxide layer 82 is grown to a controlled thickness by subjecting the trench surfaces 76, 78, and 80 of the silicon layer 38 to an oxidizing atmosphere. The oxide layer thickness is easily controlled in a scalable manner by manipulating the oxidation parameters such as the temperature or the oxygen content. The oxidation process consumes approximately 0.44 nm of silicon in the silicon layer 38 for every 1 nm of grown oxide in the layer 82. Thus, the oxide layer 38 will protrude outwardly past the sidewall spacers 70.

FIG. 6 is a cross-sectional view of the stressed MOS transistor 30 after removing the oxide layer 82 and filling the trenches 72 and 74 with SiGe material 84. Upon removing the oxide layer 82, the trench surfaces 76 and 78 are repositioned according to the amount of silicon that was consumed due to oxidation. The trench side surfaces 78 and 80 are closer in proximity to the channel region 68 due to their enlarged trench thickness as indicated by arrows 85. Consequently, the trenches 72 and 74 undercut the sidewall spacers 70, and upon filling the trenches 72 and 74, the SiGe 84 is formed beneath the sidewall spacers 70 at a desired proximity to the channel region 68. Although in theory the SiGe may nearly abut the channel region 68, in an exemplary embodiment the SiGe is brought no closer than about 3 nm to the edge of the transistor gate 62 to avoid a potential gate leakage effect.

Removal of the oxide layer 82 may be performed using an etching process using a suitable etchant. One exemplary class of etchants that removes silicon dioxide from a silicon layer includes high reactivity acids such as aqueous HF. Another oxide removal step includes placing a wafer on which the IC, including transistor 30, is formed into a chemical oxide removal module. One or more reactant gases are introduced into the chamber, where they individually react with the silicon oxide and/or react with each other in gas phase to form an oxide removal compound. According to an exemplary embodiment, a gaseous acid and a base such as ammonia gas are introduced into a chemical oxide removal chamber as separate compounds. According to a particular embodiment, gaseous NH₃ and HF are introduced into the chamber where they react to form gaseous HN₄Fₓ. The NH₄Fₓ reacts with the silicon oxide to form solid reaction product (NH₄)₂SiF₆ while the wafer is maintained at a temperature ranging between about 10 and about 30° C. Next, the solid reaction product is evaporated off of the silicon layer by heating the wafer to between about 100 and about 200° C.

After removing the silicon dioxide layer 82, the trenches 72 and 74 are filled with embedded SiGe 84. According to an exemplary method, the embedded SiGe 84 is grown by a selective epitaxial growth process that provides a higher growth rate on a [011] crystal plane than the growth rate on a [100] crystal plane. The selective epitaxial growth nucleates on the [011 crystal plane of the side surfaces as well as on the bottom surface, but a preferential growth rate on the [011] plane can be achieved in well known manner by adjusting the growth conditions such as reactant flow, growth temperature, and growth pressure. Embedded SiGe 84 is grown with a germanium concentration ranging between about 10 and about 50 atomic percent.

Although not illustrated, the structures illustrated in FIG. 6 may be completed in a conventional manner. Conventional steps include, for example, removing sidewall spacers 70 and replacing them with a single permanent sidewall spacer. The permanent sidewall spacers may be used as an ion implantation mask and conductivity determining ions are implanted into the silicon or SiGe on either side of the gate electrode to form source and drain regions. For a PMOS transistor the conductivity ions can be boron ions. As those of skill in the art will appreciate, more than one set of sidewall spacers can be used and more than one ion implantation can be carried out to create source and drain extensions, create halo implants, set threshold voltage, and the like. The sidewall spacers can also be used to form self aligned metal silicide contacts to the source and drain regions. A layer of silicide forming metal is deposited and heated to cause the metal to react with exposed silicon or SiGe to form a metal silicide. Metal that is not in contact with exposed silicon such as metal that is deposited on the sidewall spacers or the STI does not react and can be removed by etching in a solution of H₂O₂/H₂SO₄ or HNO₃/HCl. In forming a stressed MOS transistor a stress liner layer of, for example, stressed silicon nitride may be deposited over the gate electrode and metal nitride contacts. Deposition of the stress liner is followed by deposition of a dielectric layer, planarization of the dielectric layer, and etching of contact openings through the dielectric layer to the metal silicide contacts. Electrical contact to the source and drain regions can then be made by contact plugs formed in the contact openings and by interconnect metal deposition and patterning.

The foregoing embodiments have been of methods for fabricating stress enhanced PMOS transistors. Similar methods can be used to fabricate stress enhanced NMOS transistors, and the fabrication of either structure or both structures can be integrated into methods for fabricating CMOS integrated circuits including both stressed and unstressed PMOS and NMOS transistors. Fabrication of a stress enhanced NMOS transistor is similar to the methods described above except that the thin silicon layer is impurity doped P-type, the source and drain regions are impurity doped with N-type conductivity determining ions, and the embedded material that is epitaxially grown in the source and drain regions should have a substitutional atom such that the grown material has a lattice constant that is smaller than the lattice constant of the host material to create a longitudinal tensional stress on the transistor channel.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A method for fabricating a stress enhanced MOS device having a channel region at a surface of a semiconductor substrate having a first lattice parameter, the method comprising the steps of:
etching first and second trenches into the semiconductor substrate, the first trench having a first side surface, and the second trench having a second side surface, the first and second side surfaces formed astride the channel region;
oxidizing the first and second side surfaces in a controlled oxidizing environment and thereby growing an oxide region;
removing the oxide region and thereby repositioning the first and second side surfaces closer to the channel region; and
filling the first and second trenches with a material having a second lattice parameter that is different than the first lattice parameter.

2. The method according to claim 1, wherein the material having the second lattice parameter is SiGe.

3. The method of claim 1, wherein the step of filling the first and second trenches comprises epitaxially growing the material having the second parameter in the trenches.

4. The method of claim 1, further comprising the steps of:
forming a gate insulator overlying the channel region;
forming a gate electrode overlying the gate insulator; and
forming sidewall spacers astride the gate electrode,
wherein the step of etching trenches comprises aligning the first and second side surfaces with the sidewall spacers.

5. The method according to claim 4, wherein the step of removing the oxide region widens the trenches to undercut the sidewall spacers.

6. The method according to claim 1, wherein the step of removing the oxide region comprises etching the oxide using an acidic etchant.

7. The method according to claim 1, wherein the step of removing the oxide region comprises etching the oxide using a gaseous etchant.

8. The method according to claim 7, wherein the gaseous etchant comprises an acid.

9. The method according to claim 8, wherein the gaseous etchant further comprises ammonia gas.

10. A method for fabricating a stress enhanced MOS transistor comprising the steps of:
forming a gate insulator overlying a channel region in a semiconductor substrate;
forming a gate electrode overlying the gate insulator;
forming sidewall spacers astride the gate electrode,
etching first and second trenches into the semiconductor substrate, the first trench having a first side surface, and the second trench having a second side surface, the first and second side surfaces formed astride the channel region;
oxidizing the first and second side surfaces in a controlled oxidizing environment and thereby growing an oxide region;
removing the oxide region and thereby repositioning the first and second side surfaces closer to the channel region; and
filling the first and second trenches with SiGe.

11. The method of claim 10, wherein the step of filling the first and second trenches comprises epitaxially growing the SiGe in the trenches.

12. The method of claim 10, wherein the step of etching trenches comprises aligning the first and second side surfaces with the sidewall spacers.

13. The method according to claim 10, wherein the step of removing the oxide region widens the trenches to undercut the sidewall spacers.

14. The method according to claim 10, wherein the step of removing the oxide region comprises etching the oxide using an acidic etchant.

15. The method according to claim 10, wherein the step of removing the oxide region comprises etching the oxide using a gaseous etchant.

16. The method according to claim 15, wherein the gaseous etchant comprises an acid.

17. The method according to claim 16, wherein the gaseous etchant further comprises ammonia gas.

18. A stress enhanced MOS transistor comprising:
a semiconductor substrate having a channel region formed therein;
a gate insulator overlying the channel region;
a gate electrode overlying the gate insulator;
sidewall spacers formed astride the gate electrode,
first and second SiGe filled trenches formed astride the channel region and underlying the sidewall spacers.

19. The stress enhanced MOS transistor according to claim 18, wherein the SiGe in the trenches is at least 3 nm and less than 7 nm from the gate electrode.

20. The stress enhanced MOS transistor according to claim 19, wherein the sidewall spacers have a thickness of at least 7 nm.
